(19) United States
(12) Patent Application Publication
(10) Pub. No.: US 2025/0311197 A1
(43) Pub. Date: Oct. 2, 2025

(54) THREE-DIMENSIONAL DEVICES WITH AMORPHOUS OR POLYMORPHOUS CHANNEL MATERIAL

(71) Applicant: Intel Corporation, Santa Clara, CA (US)

(72) Inventor: Abhishek A. Sharma, Portland, OR (US)

(73) Assignee: Intel Corporation, Santa Clara, CA (US)

(21) Appl. No.: 18/618,232

(22) Filed: Mar. 27, 2024

(51) Int. Cl. H10B 12/00; H01L 29/06; H01L 29/423; H01L 29/778; H01L 29/78; H01L 29/786

(52) U.S. Cl. CPC H10B 12/36; H10D 30/47; H10D 30/6211; H10D 30/6735; H10D 30/6757; H10D 62/118

(57) ABSTRACT

Semiconductor devices have three-dimensional channels, such as nanoribbons or fins, formed from a polycrystalline or amorphous material. A crystalline material may be used to form a template, and a sacrificial crystalline material is removed and replaced with different material. The semiconductor channel regions may be used to form transistors, e.g., nanoribbon or FinFET transistors. The semiconductor channel regions may be used to form memory cells, e.g., stacked memory cells in which a separate memory cell is formed around different nanoribbons in the stack.

### BACKGROUND

Non-planar transistors are three-dimensional electronic devices that deviate from a traditional flat transistor design. Compared to planar transistors, non-planar transistors can provide improved control over current flow, reduced leakage, and enhanced performance, making it a key technology for smaller, faster, and more energy-efficient electronic devices. Examples of non-planar transistors include fin-shaped field-effect transistors, referred to as FinFETs, and gate-all-around (GAA) transistors. GAA transistors, also referred to as surrounding-gate transistors, have a gate material that surrounds a channel region on all sides. GAA transistors may be nanoribbon-based or nanowire-based.

Non-planar transistors typically use a monocrystalline material, such as monocrystalline silicon, to form semiconductor channels. For example, alternating layers of different monocrystalline materials (e.g., silicon and germanium) can be grown in layers. One of the materials is a sacrificial material that is removed during processing to form stacks of the channel material. A gate stack that may include one or more gate electrode materials and a gate dielectric is provided around a central portion of the semiconductor channel. A source region and a drain region are provided on the opposite ends of the semiconductor channel, forming, respectively, a source and a drain of the transistor. The source and drain regions are insulated from the gate stack, so that the voltages at the three terminals (gate, source, and drain) may be separately controlled.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a cross-section across a nanoribbon-based transistor showing the source, gate, and drain.

FIG. 1B is a cross-section of the nanoribbon-based transistor through the plane AA′ in FIG. 1A.

FIG. 2A is a cross-section across a nanoribbon-based transistor with an amorphous or polycrystalline channel showing the source, gate, and drain, according to some embodiments of the present disclosure.

FIG. 2B is a cross-section of the nanoribbon-based transistor with the amorphous or polycrystalline channel through the plane CC′ in FIG. 2A, according to some embodiments of the present disclosure.

FIG. 3A is an expanded view of a portion of FIG. 2A, according to some embodiments of the present disclosure.

FIG. 3B is an expanded view of a portion of FIG. 2B, according to some embodiments of the present disclosure.

FIG. 4A is a cross-section across a fin-shaped transistor with an amorphous or polycrystalline channel showing the source, gate, and drain, according to some embodiments of the present disclosure.

FIG. 4B is a cross-section of the fin-shaped transistor with the amorphous or polycrystalline channel through the plane EE′ in FIG. 4A, according to some embodiments of the present disclosure.

FIG. 4C is a cross-section of the fin-shaped transistor with the amorphous or polycrystalline channel through the plane FF′ in FIG. 4A, according to some embodiments of the present disclosure.

FIG. 5 is an electrical circuit diagram of an example one 1T-1C memory cell, according to some embodiments of the present disclosure.

FIG. 6A is a cross-section illustrating a stack of 1T-1C memory cells formed around nanoribbons, according to some embodiments of the present disclosure.

FIG. 6B is a gate cross-section through the plane HH′ in FIG. 6A, according to some embodiments of the present disclosure.

FIG. 7 is a flow diagram of a process for fabricating a stack of amorphous or polycrystalline semiconductor channels, according to some embodiments of the present disclosure.

FIGS. 8A and 8B are two perpendicular cross-sections illustrating alternating layers of materials, according to some embodiments of the present disclosure.

FIGS. 9A and 9B are two perpendicular cross-sections illustrating individuated stacks of the layered materials, according to some embodiments of the present disclosure.

FIGS. 10A and 10B are two perpendicular cross-sections illustrating formation of anchors around the stacks of the layered materials, according to some embodiments of the present disclosure.

FIGS. 11A and 11B are two perpendicular cross-sections illustrating removal of a first material from the stacks, according to some embodiments of the present disclosure.

FIGS. 12A and 12B are two perpendicular cross-sections illustrating a first stage of channel material deposition, according to some embodiments of the present disclosure.

FIGS. 13A and 13B are two perpendicular cross-sections illustrating further deposition of channel material, according to some embodiments of the present disclosure.

FIGS. 14A and 14B are two perpendicular cross-sections illustrating removal of the second sacrificial material, according to some embodiments of the present disclosure.

FIG. 15 illustrates top views of a wafer and dies that include one or more three-dimensional semiconductor devices with amorphous or polycrystalline channel materials in accordance with any of the embodiments disclosed herein.

FIG. 16 is a cross-sectional side view of an IC device that may include one or more three-dimensional semiconductor devices with amorphous or polycrystalline channel materials in accordance with any of the embodiments disclosed herein.

FIG. 17 is a cross-sectional side view of an IC device assembly that may include one or more three-dimensional semiconductor devices with amorphous or polycrystalline channel materials in accordance with any of the embodiments disclosed herein.

FIG. 18 is a block diagram of an example computing device that may include one or more three-dimensional semiconductor devices with amorphous or polycrystalline channel materials in accordance with any of the embodiments disclosed herein.

FIG. 19 is a block diagram of an example processing device that includes an IC device with one or more three-dimensional semiconductor devices with amorphous or polycrystalline channel materials in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Described herein are IC devices that include non-planar or three-dimensional transistors, such as nanoribbon-based transistors and fin-shaped transistors, with amorphous or polycrystalline channel materials. The transistors described herein may be used in various applications, including logic devices and as access transistors for memory devices. Non-planar transistors provide several advantages over planar transistor architectures. For example, non-planar transistors provide improved electrostatic transistor control and faster transistor speeds relative to other transistor architectures. For certain applications, nanoribbon-based channels are particularly advantageous, providing increased drive current at smaller scales relative to other non-planar architectures.

Transistors typically include a gate stack coupled to a semiconductor channel, which may be a nanoribbon or a stack of nanoribbons. A gate stack often includes a gate electrode and a gate dielectric, with the gate dielectric formed between the gate electrode and the channel material. In a nanoribbon transistor, the gate dielectric is formed around each nanoribbon, and the gate electrode is formed over and around the gate dielectric, including in spaces between adjacent nanoribbons in the stack. In some implementations of nanoribbon transistors, the gate dielectric is omitted. A source region is formed at one end of the nanoribbons, and a drain region is formed at the opposite end of the nanoribbons, thus realizing a three-terminal device.

As noted above, single-crystal materials, such as monocrystalline silicon, are typically used for three-dimensional transistor architectures. For example, for a nanoribbon transistor, alternating layers of a channel material and a sacrificial material are grown over a substrate, such as a silicon substrate. The channel material and sacrificial material may be chosen to have a similar crystal structure to each other, so that even layers of the two materials may be grown over each other.

While monocrystalline silicon has several advantageous properties (e.g., a moderate bandgap, fairly high electron and hole mobility, relatively high breakdown voltage, etc.), alternative semiconductor materials have different electrical and mechanical properties that may make them desirable for forming transistor channels in different contexts. For example, some semiconductor materials, such as gallium arsenide, indium gallium arsenide, and other indium alloys, have higher carrier mobilities than silicon, which can enable faster operation and superior high-frequency performance. Silicon has a fairly high breakdown voltage, but other materials have higher breakdown voltages, which may be better suited for high-power operations or wider temperature ranges.

The IC devices described herein use a monocrystalline growth process to form a template, and then replace a sacrificial monocrystalline material with a different semiconductor material, e.g., an amorphous or polycrystalline material, which is used as a semiconductor channel in a transistor. The replacement material can be selected to achieve particular electrical and/or mechanical properties, e.g., higher mobility, a different bandgap, durability at different operating temperatures or voltages, durability in further processing steps (e.g., high-temperature fabrication), or other factors.

In some embodiments, the three-dimensional transistors described herein are used in memory devices, e.g., as access transistors in dynamic random access memory (DRAM) cells. One challenge with DRAM cells is that, given a usable surface area of a substrate, there are only so many transistors that can be formed in that area, placing a significant limitation on the density of memory cells incorporating such transistors. In conventional solutions, attempts to increase memory density have included decreasing the critical dimensions of the memory cells, which requires ever-increasing process complexity and cost, resulting in diminishing returns and expected slow pace of memory scaling for future nodes. Embodiments of the present disclosure may enable increased memory density using a vertically stacked memory design, where a stack of nanosheets is used to provide a stack of individually-controlled DRAM memory cells. In particular, each nanosheet in the stack can be used to form an independent transistor, and a capacitor can be coupled to each nanosheet in the stack.

Nanoribbons are often small structures, with a low amount of current passing through each individual nanoribbon. In many nanoribbon-based transistors, multiple nanoribbons are used together in a single transistor to provide adequate current flow through the transistor. In general, when transistors operate at lower temperatures, they have improved performance. For example, electron mobility in semiconductors improves at lower temperatures, which can lead to increased drive currents across semiconductor regions, e.g., across transistors or individual nanoribbons. In addition, transistors at lower temperatures generally experience lower leakage than transistors operating at higher temperatures. These factors can allow smaller transistors when the IC device is operating at a lower temperature. In addition, the electron mobility in a single nanoribbon may be enhanced through selection of a high-mobility channel material.

In some cases, e.g., in low-temperature applications where the drive current through an individual nanoribbon is greater, transistors can be built around individual nanoribbons in a stack, rather than around full stacks of nanoribbons. For a memory application, each nanoribbon in the stack can serve as the basis for an access transistor. Capacitors may be similarly vertically stacked, e.g., a capacitor can be coupled to the end of each nanoribbon, thus realizing a vertical stack of 1T-1C memory cells.

Memory devices, and assemblies including such memory devices (e.g., IC devices, electronics packages, etc.), that include a nanoribbon-based access transistor with a non-crystalline channel material coupled to a capacitor are described herein. A stack of nanoribbons may be used to form a stack of memory devices. A transistor is formed around each nanoribbon, and a capacitor is formed at the end of each nanoribbon. Thus, multiple 1T-1C memory cells may be stacked vertically, with a nanoribbon forming the base structure of each 1T-1C memory cell.

A gate line may be formed across multiple memory cells in different stacks. For example, if multiple stacks of memory cells are arranged side-by-side, a first gate line spans the top nanoribbon of each stack, a second gate line spans the next nanoribbon down in each stack, etc. Connections from the different gate lines to a metallization layer may be formed in a staircase fashion, as illustrated in the figures. The gate lines may act as the word line to the access transistors. A single source or drain (S/D) region may be coupled to all of the nanoribbons in a given stack and act as a bit line to the access transistors. The end of the nanoribbon on the opposite side of the gate from the S/D region is coupled to one capacitor plate. For example, a first conductive layer (forming a first capacitor plate) may be formed over or around the end of the nanoribbon opposite the S/D region, a dielectric layer formed over or around the first conductive layer, and a second conductive layer (forming a second capacitor plate) formed over or around the dielectric layer. The second conductive layers of a stack of transistors may be arranged in a staircase fashion, with connections to the metallization layer forming different plate lines to each capacitor.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

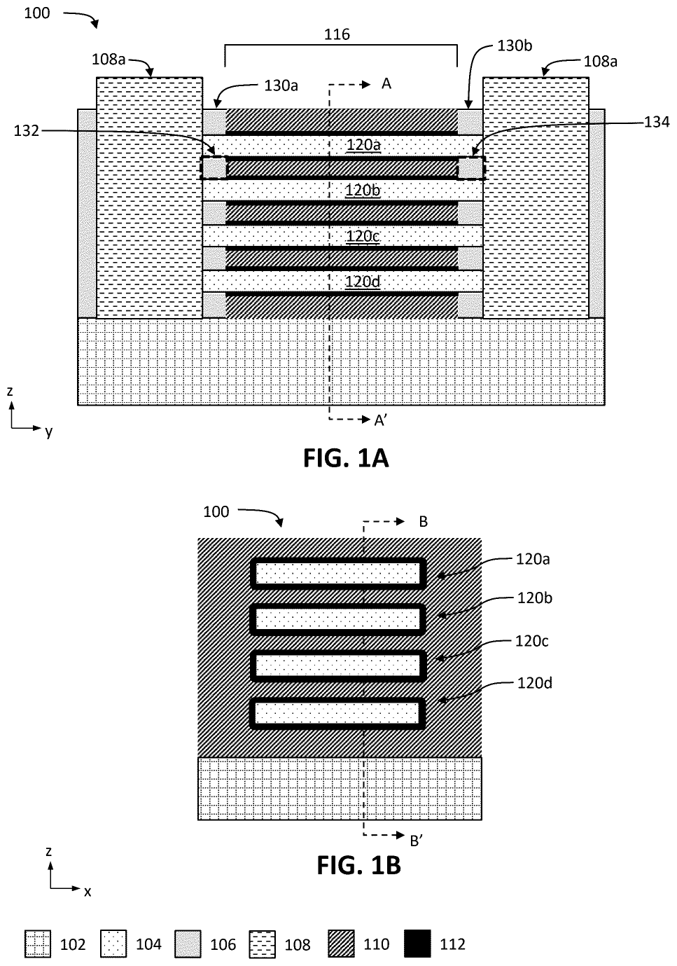

For convenience, if a collection of drawings designated with different letters are present, e.g., FIGS. 1A-1B, such a collection may be referred to herein without the letters, e.g., as “FIG. 1.”

### Example Nanoribbon Transistor

FIGS. 1A-1B illustrate an example architecture of a nanoribbon-based transistor. FIG. 1A is a cross-section across a transistor 100 showing the source, gate, and drain. FIG. 1B is a cross-section across the gate regions of the transistor 100. FIG. 1B is a cross-section through the plane AA′ in FIG. 1A, and FIG. 1A is a cross-section through the plane BB′ in FIG. 1B. The nanoribbon-based transistor 100 illustrates certain structures and materials that may be used in the transistors and memory cells discussed further below.

A number of elements referred to in the description of FIGS. 1A, 1B, 2-4, 6, and 7-14 and with reference numerals are illustrated in these figures with different patterns, with a legend at the bottom of the page showing the correspondence between the reference numerals and patterns. The legend illustrates that FIGS. 1A and 1B use different patterns to show a support structure 102, a channel material 104, a dielectric material 106, a source or drain (S/D) region 108, a gate electrode 110, and a gate dielectric 112.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

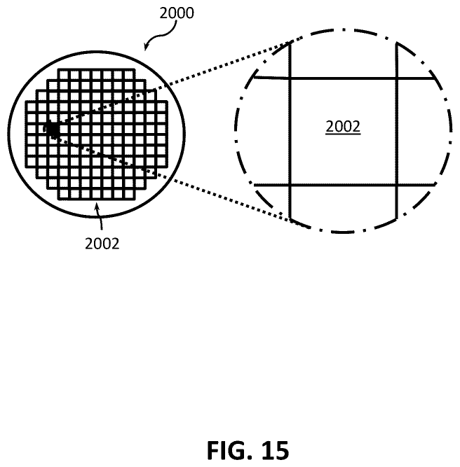

In general, implementations of the present disclosure may be formed or carried out on a support structure, e.g., the support structure 102 illustrated in FIG. 1. The support structure 102 may be, e.g., a substrate, a die, a wafer or a chip. For example, the support structure may be the wafer 1500 of FIG. 15, discussed below, and may be, or be included in, a die, e.g., the singulated die 1502 of FIG. 15, discussed below. The support structure 102 extends along the x-y plane in the coordinate system shown in FIG. 1. In some embodiments, a support structure 102 may be used during a fabrication process and later removed. For example, a top side of the transistor 100 may be attached to a second support structure (e.g., a second one of the support structures 102, which may be referred to as a carrier structure), and the support structure 102 over which the transistor 100 is formed may be removed to expose the back side of the transistor 100.

In some embodiments, a support structure may be a substrate that includes silicon and/or hafnium. More generally, the support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device including one or more nanoribbon transistors, as described herein, may be built falls within the spirit and scope of the present disclosure.

In FIGS. 1A and 1B, a transistor 100 is formed over a support structure 102. The transistor 100 includes a channel material 104 formed into four nanoribbons stacked on top of each other. In other examples, the transistor 100 may include more or fewer nanoribbons, e.g., one, two, three, five, six or more nanoribbons. The channel material 104 may be a semiconductor, such as silicon or other semiconductor materials described herein.

The transistor 100 includes nanoribbons 120a, 120b, 120c, and 120d, referred to collectively as nanoribbons 120 or individually as a nanoribbon 120. Each nanoribbon 120 is at a different height in the z-direction in the orientation shown in FIGS. 1A and 1B, i.e., a different distance from the support structure 102, where the nanoribbon 120a is the greatest distance from the support structure 102, and the nanoribbon 120d is the smallest distance from the support structure 102. S/D regions 108a and 108b are formed at either end of the nanoribbon channels 120, as illustrated in FIG. 1A.

In general, to form nanoribbon channels such as the nanoribbon channels 120, alternating layers of material are deposited over the support structure 102. In this example, alternating layers of the channel material 104 and a sacrificial material may be deposited over the support structure 102. The sacrificial material is removed from the stack and replaced with other material, e.g., material for forming a gate stack 116, so the sacrificial material is not shown in FIG. 1. The channel material 104 and sacrificial materials include different materials. In one example, the channel material 104 is silicon, while the sacrificial material includes silicon and germanium. The sacrificial material may be chosen to have a similar crystal structure to the channel material 104, so that monocrystalline layers of the channel material 104 (or substantially monocrystalline layers, e.g., with a grain size of at least 5 nanometers, at least 20 nanometers, at least 50 nanometers, or at least 100 nanometers) and monocrystalline layers of the sacrificial material (or substantially monocrystalline layers) may be formed over each other. In different examples, the channel material 104 and/or the sacrificial material may be formed of any suitable single-crystal material, such as sapphire, quartz, silicon, a compound of silicon (e.g., silicon oxide), indium phosphide, germanium or a germanium alloy (e.g., silicon germanium), gallium, arsenic (e.g., an arsenide 11 compound, where arsenic III is in combination with another element such as boron, aluminum, gallium, or indium), or any group III-V material (i.e., materials from groups III and V of the periodic system of elements).

The S/D regions 108 may be formed from one or more layers of doped semiconductors, metals, metal alloys, or other materials. For example, the S/D regions 108 may include a doped semiconductor, such as silicon or another semiconductor doped with an N-type dopant or a P-type dopant. The S/D regions 108 may include multiple layers with different levels of conductivity, e.g., a doped semiconductor followed by a more highly doped semiconductor, or a semiconductor followed by metal.

A central portion of each of the nanoribbon channels 120 is surrounded by a gate stack 116, which in this example, includes a gate electrode 110 and gate dielectric 112. Nanoribbon transistors often include a gate dielectric that surrounds the nanoribbon channels 120, and a gate electrode that surrounds the gate dielectric. While not specifically shown, in some cases, the gate dielectric 112 around each nanoribbon channel 120 includes multiple layers, e.g., an oxide layer and a high-k dielectric layer. The oxide layer may be grown directly on the nanoribbon channels 120, and the high-k dielectric may surround the oxide. The oxide may include oxygen in combination with the channel material 104. For example, if the nanoribbon channels are formed from silicon, the gate dielectric 112 may include a layer of silicon oxide. The high-k dielectric may be formed over the oxide. The gate electrode 110 surrounds the gate dielectric 112, e.g., the high-k dielectric (if included). In this example, the gate electrode 110 is above and below the nanoribbon stack, and between adjacent nanoribbons 120.

The gate electrode 110 includes a conductive material, such as a metal. The gate electrode 110 may include at least one P-type work function metal or N-type work function metal, depending on whether the transistor 100 is a PMOS transistor or an NMOS transistor. For a PMOS transistor, metals that may be used for the gate electrode 110 may include, but are not limited to, ruthenium, palladium, platinum, cobalt, nickel, and conductive metal oxides (e.g., ruthenium oxide). For an NMOS transistor, metals that may be used for the gate electrode 110 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). The gate electrode 110 may include a stack of two or more metal layers, where one or more metal layers are work function metal layers and at least one metal layer is a fill metal layer.

The gate dielectric 112 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. The gate dielectric 112 may have a thickness between about 0.5 nanometers and 3 nanometers, including all values and ranges therein, e.g., between about 1 and 3 nanometers, or between about 1 and 2 nanometers.

Regions of the transistor 100 outside of the nanoribbons 120, gate stack 116, and S/D regions 108 are filled in with a dielectric material 106. In the region between the gate stack 116 and the S/D regions 108, the dielectric material 106 forms a series of cavity spacers. Cavity spacers, also referred to as “dimple spacers” or “inner spacers,” provide electrical isolation between the S/D regions 108 formed at the ends of the nanoribbons and the gate electrode 110 deposited around the nanoribbons 120.

FIG. 1 illustrates a single nanoribbon transistor 100. In IC devices, many similar or identical transistors are arranged within a transistor layer. The dielectric material 106 and/or different dielectric materials may provide isolation between different transistors, or between other conductive materials in or near the transistor layer.

Example Transistors with Replacement Channel Material

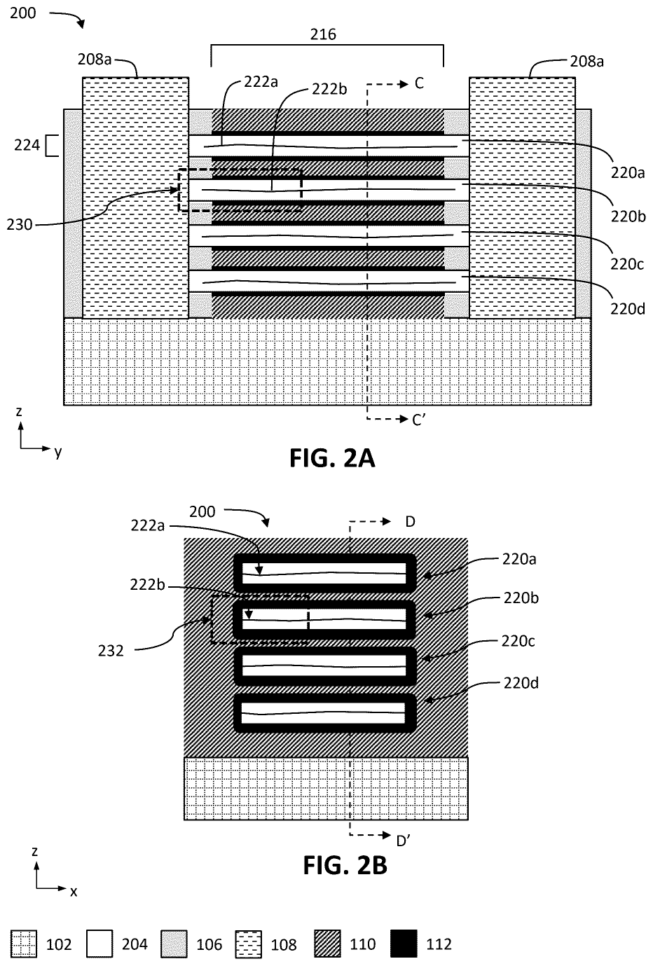

In some nanoribbon transistors, such as in the example of FIG. 1, the channel material 104 is formed in layers, as described above. In such transistors, the channel material 104 is substantially monocrystalline, and generally has a uniform structure throughout the nanoribbons 120. As disclosed herein, transistors can be formed that include a channel material that is regrown after an initial template is formed, where the template has the desired channel structure. The material (e.g., the single-crystal material) in the template is removed and replaced with a different channel material. As a result of this regrowth process, the transistor channel may have a seam that is visible in cross-sections through the channel. Two example transistors with regrown channels and seams are illustrated in FIGS. 2-4.

FIG. 2A is a cross-section across a nanoribbon-based transistor 200 with an amorphous or polycrystalline channel showing the source, gate, and drain, according to some embodiments of the present disclosure. FIG. 2B is a cross-section through the plane CC′ in FIG. 2A, and FIG. 2A is a cross-section through the plane DD′ in FIG. 2B.

Turning first to FIG. 2A, a stack of four nanoribbons 220a, 220b, 220c, and 220d are over a support structure 102, which may be the support structure 102 described with respect to FIG. 1. The nanoribbons 220a, 220b, 220c, and 220d are referred to collectively as nanoribbons 220 or individually as a nanoribbon 220. A transistor is formed around the stack of nanoribbons 220.

The nanoribbons 220 may be any three-dimensional semiconductor structures around which the memory cells described herein may be formed, including, for example, nanowires with a square or circular cross-section, or nanosheets with a wider rectangular cross section. The term nanosheet is sometimes used to highlight the relative breadth and thinness of a particular nanoribbon structure. For example, the term nanosheet may indicate that a structure has a small height (in the z-direction in the example coordinate system) and a broader width (into the page in FIG. 2A, i.e., in the x-direction in the coordinate system shown) compared to other nanostructures, like nanowires. In other embodiments, the nanoribbons 220 may have cross-sections that are squares with rounded corners, rectangles with rounded corners, ovals, or other shapes.

The nanoribbons 220 each have an elongated structure that extends over the support structure 102. Each nanoribbon 220 extends primarily in the y-direction in the coordinate system used in FIGS. 2A and 2B, and thus the nanoribbon structures are considered to be elongated in this direction. The direction in which the nanoribbons 220 extend is parallel to the support structure 102; this direction in which the nanoribbons 220 extend is also parallel to the other nanoribbons in the stack.

Each nanoribbon 220 is at a different height in the z-direction in the orientation shown in FIGS. 2A and 2B, i.e., a different distance from the support structure 102, where the nanoribbon 220a is the greatest distance from the support structure 102, and the nanoribbon 220d is the smallest distance from the support structure 102. While four nanoribbons 220a-220d are shown, in other embodiments, the transistor 200 may include more or fewer nanoribbons, e.g., one, two, three, five, six or more nanoribbons 220, and a corresponding number of memory cells.

Two S/D regions 208a and 208b are at opposite ends of the nanoribbons 220, as illustrated in FIG. 2A. The S/D regions 208 may include the S/D materials 108 described with respect to FIG. 1. A central portion of the nanoribbons 220 is surrounded by a gate stack 216, which like the gate stack 116, includes a gate electrode 110 and gate dielectric 112. The gate dielectric 112 surrounds the nanoribbons 220, and the gate electrode 110 surrounds the gate dielectric 112. The gate dielectric 112 and gate electrode 110 may include any of the materials described with respect to FIG. 1. As described with respect to FIG. 1, in some cases, the gate dielectric 112 includes multiple layers, e.g., an oxide layer and a high-k dielectric layer. The oxide layer may be grown directly on the nanoribbons 320, and the high-k dielectric may surround the oxide. The oxide may include oxygen in combination with the channel material 104. The gate electrode 110 may also include multiple layers, e.g., layers of different conductive materials.

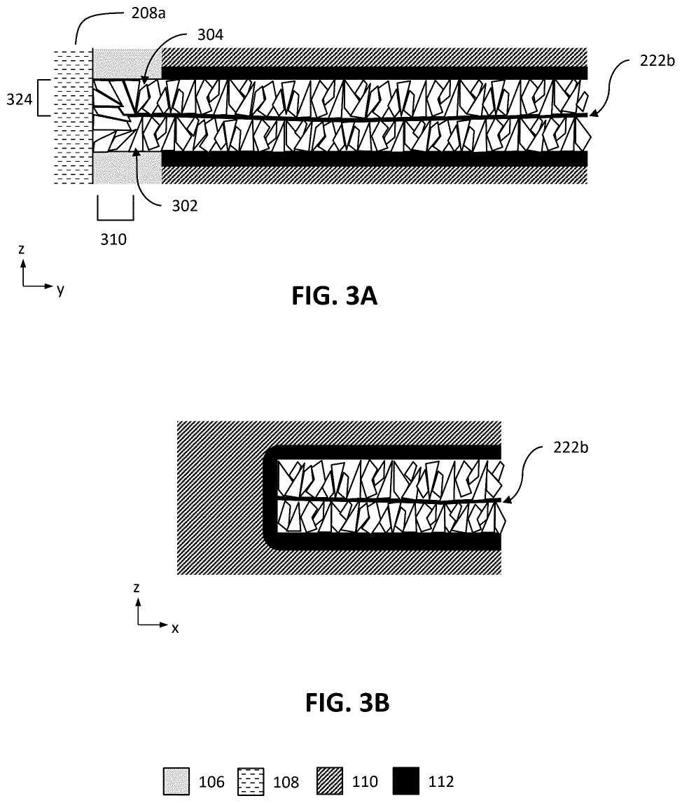

The nanoribbons 220 include the channel material 204, which is different from the channel material 104 described with respect to FIG. 1. The channel material 204 may generally include an amorphous material or a polycrystalline material. An amorphous material is a material that does not have an apparent crystal structure. A polycrystalline material is a material that includes crystals at a smaller grain size than a monocrystalline material. For example, a polycrystalline material may have a grain size of 20 nm or lower, e.g., a grain size between 1 nm and 20 nm, or 10 nm or lower, e.g., between 1 nm and 10 nm, or 5 nm or lower, e.g., between 1 nm and 5 nm. If the channel material 204 is polycrystalline, it may have a grain size that is generally half or less than half of the height 224 of the nanoribbons 220, where height is measured in the z-direction in the coordinate system shown. Example grains are illustrated in FIGS. 3A and 3B, discussed further below.

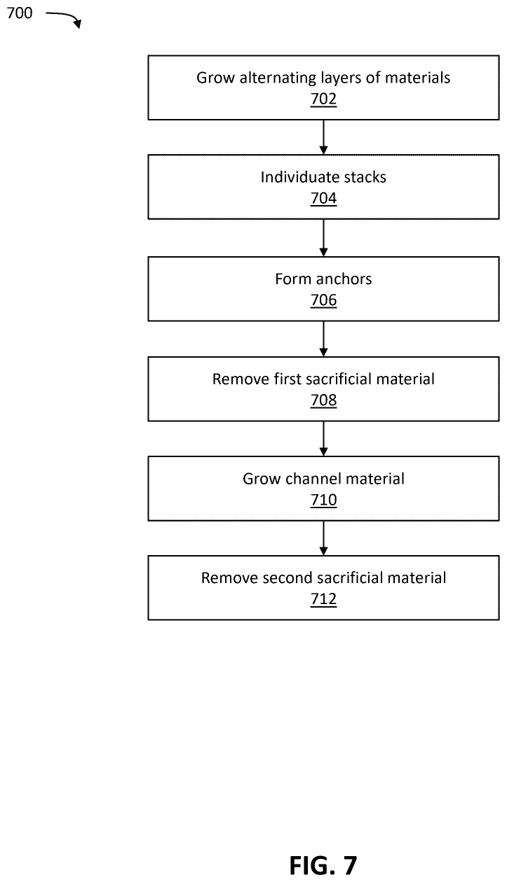

The channel material 204 may include any semiconductor material that can be regrown using a conformal deposition process, such as atomic layer deposition (ALD) or chemical vapor deposition (CVD). Conformal deposition generally refers to deposition of a certain coating on any exposed surface of a given structure. A conformal coating may, therefore, be understood as a coating that is applied to exposed surfaces of a given structure, and not, for example, just to the horizontal surfaces. An example process of forming the channel material 204 is illustrated and described with respect to FIGS. 7-14.

The channel material 204 may include N-type or P-type materials systems. In some embodiments, the channel material 204 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. The channel material 204 may include one or more of cobalt oxide, copper oxide, ruthenium oxide, nickel oxide, niobium oxide, copper peroxide, indium telluride, molybdenite, molybdenum diselenide, tungsten diselenide, tungsten disulfide, molybdenum disulfide, N- or P-type amorphous or polycrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc.

In some cases, multiple channel materials may be included within an IC device. For example, an IC device may include both N-type metal-oxide-semiconductor (NMOS) transistors and P-type MOS (PMOS) transistors, e.g., alternating rows of NMOS and PMOS transistors. NMOS and PMOS logic can use different types of channel material 204, e.g., amorphous or polycrystalline silicon may be used to form an N-type semiconductor channel, while amorphous or polycrystalline silicon germanium may be used to form a P-type semiconductor channel. In some cases, a single channel material 204 is used (e.g., silicon), and different portions (e.g., channel material to form different transistors) may include different dopants, e.g., N-type dopants for NMOS transistors and P-type dopants for PMOS transistors.

The nanoribbons 220 have seams 222 that may be visible in the cross-sections through the nanoribbons 220. For example, in FIG. 2A, the seams 222a and 222b extend through the nanoribbons 220a and 220b; similar seams are visible in the nanoribbons 220c and 220b. In the cross-section of FIG. 2A, the seams 222 extend substantially in the y-direction, e.g., parallel to the upper surface or upper side of the support structure 102, and in a direction extending between the two S/D regions 208a and 208b. The seams 222 extend most of the way, but not all the way, across the nanoribbons 220 in the y-direction.

FIG. 2B illustrates the seams 222 in a perpendicular cross-section through the gate stack 216. In the cross-section of FIG. 2B, the seams 222 extend substantially in the x-direction, e.g., parallel to the upper surface or upper side of the support structure 102, and in a direction perpendicular to the direction between the two S/D regions 208a and 208b. In the cross-section of FIG. 2B, the seams 222 extend through the nanoribbons 220. The structure of the seams 222 (e.g., extending fully through the nanoribbons 220 in the x-direction and partially through the nanoribbons 220 in the y-direction) may result from the process used to form the nanoribbons 220, e.g., the process described with respect to FIGS. 7-14.

The seams 222 are discontinuities in the channel material 204. As one example, for a given nanoribbon 220, the seam 222 is an air gap between two portions of the channel material 204, e.g., an upper portion that extends downward extending from an upper face or upper side of the channel material 204 (i.e., a side extending downward from an upper layer of the gate dielectric 112), and a lower portion that extends upward from a lower side or lower face of the channel material 204 (i.e., a side extending upward from a lower layer of the gate dielectric 112). As another example, the seam 222 is a discontinuity in the material structure (e.g., between grains of a polycrystalline material) between the upper and lower portions of the channel material 204 in the nanoribbon 220. As yet another example, the seam 222 is a chemical difference between the two portions of the channel material 204 of the nanoribbon 220, or the seam has a different chemical composition than other regions of the channel material 204 (e.g., if the channel material 204 includes a combination of silicon and a dopant, the seam 222 has a different percentage of silicon and, correspondingly, a different percentage of the dopant from other portions of the channel material 204).

While FIG. 2B illustrates the nanoribbons 220 with rectangular cross-sections, as noted above, in other embodiments, the cross-sections of the nanoribbons 220 in the x-z plane, and other nanoribbons described herein, may have other cross sections, e.g., nanoribbons may be narrower or wider than illustrated in the figures.

FIG. 3A is an expanded view of the outlined portion 230 of FIG. 2A, according to some embodiments of the present disclosure. FIG. 3A illustrates example crystal grains (also referred to as crystals), including the grains 302 and 304, of a polycrystalline channel material. As shown in FIG. 3A, in the area above and below the gate electrode 110 and gate dielectric 112, the grains are generally oriented vertically, e.g., with their longest dimensions extending between the gate dielectric 112 and the seam 222b. This may be because the grains grow downward from the top and upward from the bottom, as described further below. The grains have a maximum height 324, where height is measured in the z-direction (i.e., a direction perpendicular to the support structure 102), that is half of approximately half of the height 224 of the nanoribbons 220. The maximum height is due to the crystal growth stopping at the seam 222, which is at around the middle of the nanoribbons 220, e.g., approximately mid-way between a base and a top of the nanoribbons 220.

In the region 310, which extends between the S/D region 208a and the seam 222b, the orientation of the crystal grains may be different from the orientation in the rest of the nanoribbons 220. In particular, at the sides of the nanoribbons along the S/D region 208, the crystal grains may extend sideways from the S/D region 208 (e.g., sideways from the S/D region 208a, as shown in FIG. 3A), and the orientation may curve around the corners between the S/D regions 208 and the tops and bottoms of the nanoribbons 220. This may be because the grains grow sideways from the S/D regions 208, or from a sacrificial anchor material along the ends of the nanoribbons 220. The seams 222 are formed where the sideways growth meets the growth from the tops and bottoms of the nanoribbons 220; thus, the seams 222 do not extend all the way to the S/D regions 208 in the y-direction.

FIG. 3B is an expanded view of the outlined portion 232 of FIG. 2B, according to some embodiments of the present disclosure. FIG. 3B illustrates that in the x-z plane, the seams 222 extend to the ends of the nanoribbons 220, and the crystal grains are substantially vertically oriented throughout the width of the nanoribbons 220.

A process of growing a template with a monocrystalline material, and then replacing the monocrystalline material with a polycrystalline or amorphous channel material, may be used for other three-dimensional transistor architectures. In another example, polycrystalline or amorphous materials are used to form fins in a fin-shaped transistor.

FinFETs are transistors having a non-planar architecture where a fin, formed of one or more semiconductor materials, extends away from a base (where the term “base” refers to any suitable support structure on which a transistor may be built, e.g., a substrate). A portion of the fin that is closest to the base may be enclosed by an insulator material. Such an insulator material, typically an oxide, is commonly referred to as a “shallow trench isolation” (STI), and the portion of the fin enclosed by the STI is typically referred to as a “subfin portion” or simply a “subfin.” A gate stack that includes at least a layer of a gate electrode material and, optionally, a layer of a gate dielectric may be provided over the top and sides of the remaining upper portion of the fin (i.e., the portion above and not enclosed by the STI), thus wrapping around the upper-most portion of the fin. The portion of the fin over which the gate stack wraps around is typically referred to as a “channel portion” of the fin because this is where, during operation of the transistor, a conductive channel forms, and is a part of an active region of the fin. Two S/D regions are provided on the opposite sides of the gate stack, forming a source and a drain terminal of a transistor. FinFETs may be implemented as “tri-gate transistors,” where the name “tri-gate” originates from the fact that, in use, such transistors may form conducting channels on three “sides” of the fin. FinFETs potentially improve performance relative to single-gate transistors and double-gate transistors.

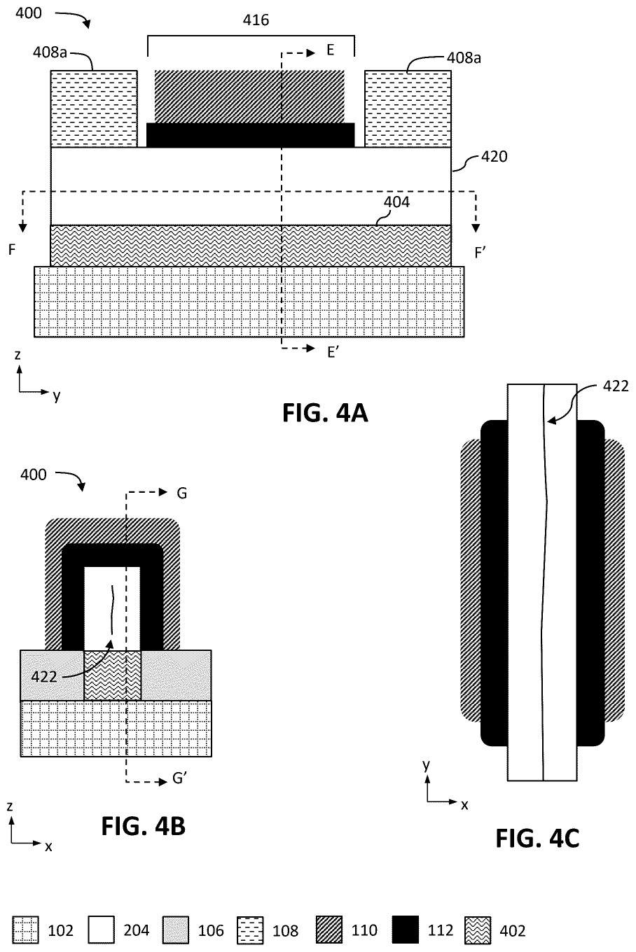

FIGS. 4A, 4B, and 4C are three cross-sections across a fin-shaped transistor 400 with an amorphous or polycrystalline channel. FIG. 4A is a cross-section through the source, gate, and drain. FIG. 4B is a cross-section through the gate, e.g., through the plane EE′ in FIG. 4A. FIG. 4C is a cross-section through the channel, e.g., through the plane FF′ in FIG. 4A. The transistor device 400 includes a fin 420 of the channel material 204, which may any of the channel materials 204 described above. A gate stack 416 is formed over and around the fin 420, surrounding the fin 420 on three sides, as illustrate din FIG. 4B. Two S/D regions 408a and 408b are on either side of the fin 420, and include the S/D material 108.

In this example, the channel material 204 of the fin 420 is over a subfin 404 formed from subfin material 402. The dielectric material 106 is on either side of the subfin 404, as shown in FIG. 4B. In some embodiments, the subfin material 402 is the template material used during fabrication of the transistor 400, e.g., a monocrystalline silicon or another monocrystalline material. While the fin portion of the template material is removed and replaced with the channel material 204, the template material remains in the subfin. In other embodiments, the template material in the subfin 404 may be evacuated and replaced along with the channel material; in such embodiments, the subfin material 402 may be the same as channel material 204. In such embodiments, the seam 422 may also extend into the subfin 404.

A seam 422, illustrated in FIGS. 4B and 4C, extends through the fin 420. The seam 422 generally extends in the z-y plane; the cross-section illustrated in FIG. 4A may be offset from the seam. For example, FIG. 4A illustrates the cross-section through the plane GG′ in FIG. 4B. In the x-z cross-section through the gate stack 416, the seam 422 extends partially up the height 424; the seam 422 does not extend to the top of the fin 420 or down to the bottom of the fin 420. If the channel material 204 is a polycrystalline material, the grains may be oriented relative to the seam 422 in a similar manner to the grains shown in FIG. 3A. In particular, the grains may generally be oriented horizontally between the seam 422 and the sides of the fin 420, but the grains may wrap around the seam 422 at the top and bottom of the fin 420, e.g., extending substantially vertically from the top and bottom of the fin 420.

In the cross-section through the fin 420 shown in FIG. 4C, the seam 422 extends to the ends of the fin 420, e.g., from an end coupled to a first S/D region 408a to the end coupled to the second S/D region 408b. If the channel material 204 is a polycrystalline material, the grains of the fin 420 in FIG. 4C may be oriented relative to the seam 422 in a similar manner to the grains shown in FIG. 3B.

### Example 1T-1C Memory Cell

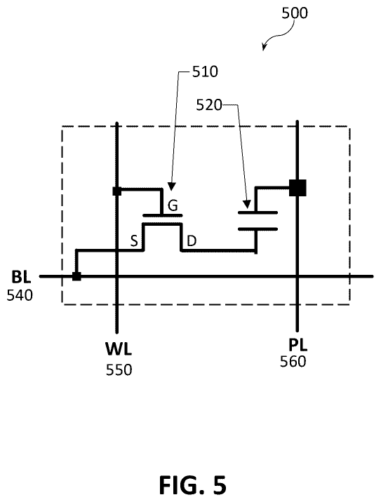

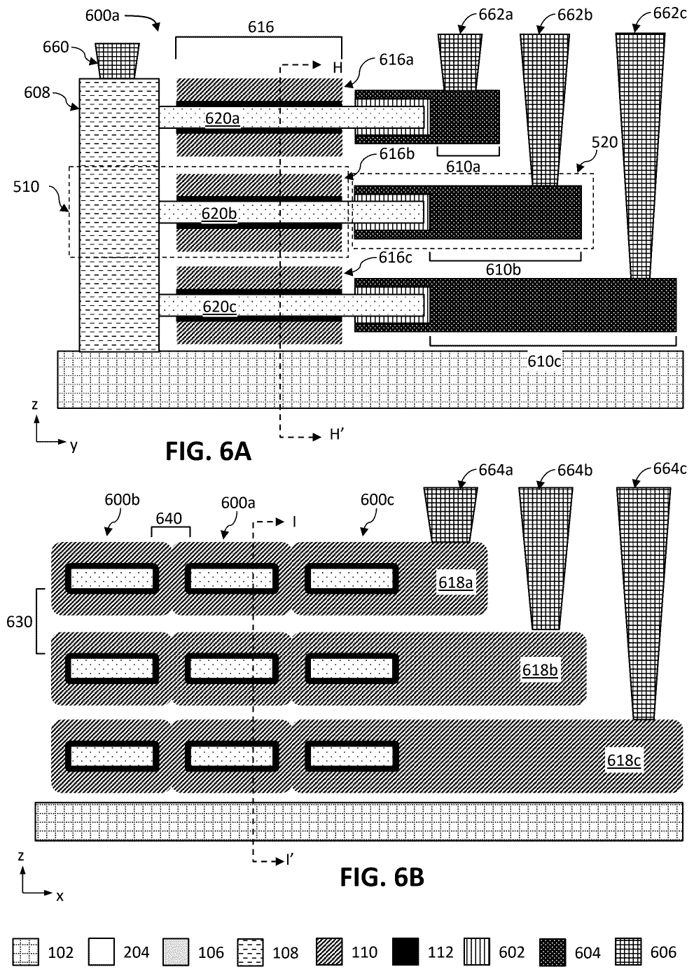

Any of the transistors described above may be used in a memory cell, e.g., as an access transistor for a DRAM cell. FIG. 5 is an electrical circuit diagram of an example one access transistor (1T) and one capacitor (1C) (1T-1C) memory cell 500, according to some embodiments of the present disclosure. The 1T-1C cell 500 is an example DRAM memory cell that may include a three-dimensional transistor with amorphous or polycrystalline channel materials. For example, FIG. 6A, discussed below, shows a stack of three memory cells; each of the three memory cells in FIG. 6 is represented by the memory cell 500.

A DRAM memory cell typically includes a capacitor for storing a bit value or a memory state (e.g., logical “1” or “0”) of the cell and an access transistor controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”). The capacitor of a 1T-1C memory cell may be coupled to one source/drain (S/D) region/terminal of the access transistor (e.g., to the source region of the access transistor), while the other S/D region of the access transistor may be coupled to a bitline (BL), and a gate terminal of the transistor may be coupled to a wordline (WL). Since such a memory cell can be fabricated with as little as a single access transistor, it can provide higher density and lower standby power versus some other types of memory in the same process technology, e.g., SRAM.

The 1T-1C cell 500 illustrates an access transistor 510 and a capacitor 520. The access transistor 510 has a gate terminal, a source terminal, and a drain terminal, indicated in the example of FIG. 5 as terminals G, S, and D, respectively. In the following, the terms “terminal” and “electrode” may be used interchangeably. Furthermore, for S/D terminals, the terms “terminal” and “region” may be used interchangeably.

As shown in FIG. 5, in the 1T-1C cell 500, the gate terminal of the access transistor 510 is coupled to a WL 550, one of the S/D terminals of the access transistor 510 (in this example, the source terminal, S) is coupled to a BL 540, and the other one of the S/D terminals of the access transistor 510 (in this example, the drain terminal, D) is coupled to a first electrode of the capacitor 520. As also shown in FIG. 5, the other electrode of the capacitor 520 is coupled to a capacitor plateline (PL) 560. As is known in the art, WL, BL, and PL may be used together to read and program the capacitor 520.

Each of the BL 540, the WL 550, and the PL 560, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

### Example Stacks of 1T-1C Memory Cells Around Nanoribbons

FIG. 6A is a cross-section illustrating a stack 600a of 1T-1C memory cells formed around nanoribbons, according to some embodiments of the present disclosure. FIG. 6B is a gate cross-section through the plane HH′ in FIG. 6A. FIG. 6A illustrates the plane II′ in FIG. 6B.

Turning first to FIG. 6A, a stack of three nanoribbons 620a, 620b, and 620c are over a support structure 102, which may be the support structure 102 described with respect to FIG. 1. An access transistor and a capacitor of a memory cell are formed around each of the nanoribbons 620. For example, an access transistor 510 is formed around a left side of the nanoribbon 620b, and a capacitor 520 is formed around a right side of the nanoribbon 620b. Similarly, an access transistor 510 is formed around the left side of the nanoribbons 620a and 620c, while a capacitor 520 is formed around the right side of the nanoribbons 620a and 620c.

The nanoribbons 620 include the channel material 1204, which may be the channel material 204 described with respect to FIG. 2. The nanoribbons 620a, 620b, and 620c are referred to collectively as nanoribbons 620 or individually as a nanoribbon 620. As described with respect to FIG. 2, the nanoribbons 620 may have different shapes, and in particular, different cross-sections through the x-z plane, than are illustrated in FIG. 6.

An S/D region 608 is at one end of the nanoribbons 620, as illustrated in FIG. 6A. The S/D region 608 may include the S/D materials 108 described with respect to FIG. 1. A central portion of each of the nanoribbons 620 is surrounded by a gate stack 616, which like the gate stack 116, includes a gate electrode 110 and gate dielectric 112. The gate dielectric 112 surrounds the nanoribbons 620, and the gate electrode 110 surrounds the gate dielectric 112. The gate dielectric 112 and gate electrode 110 may include any of the materials described with respect to FIG. 1. As described with respect to FIG. 1, in some cases, the gate dielectric 112 includes multiple layers, e.g., an oxide layer and a high-k dielectric layer. The oxide layer may be grown directly on the nanoribbons 620, and the high-k dielectric may surround the oxide. The oxide may include oxygen in combination with the channel material 204. The gate electrode 110 may also include multiple layers, e.g., layers of different conductive materials.

In FIG. 1 and FIG. 2, the gate electrode 110 spanned areas between adjacent nanoribbons 120 or 220, e.g., in FIG. 2, the gate electrode 110 filled in the area between the nanoribbons 220a and 220b. In contrast, in FIG. 6A, the gate electrodes around different nanoribbons 620 are physically and electrically isolated from each other. Thus, each nanoribbon 620 has its own independent gate stack, i.e., the nanoribbon 620a is surrounded by the gate stack 616a, the nanoribbon 620b is surrounded by the gate stack 616b, and the nanoribbon 620c is surrounded by the gate stack 616c. To obtain independent gate stacks, the distance 330 (illustrated in FIG. 6B) between adjacent nanoribbons 620 in the stack may be relatively large, e.g., larger than the distance between adjacent nanoribbons 220 in the transistor 200 shown in FIG. 2. The independent gate stacks enables the formation of independent access transistors 510 around each nanoribbon 620. In particular, referring to FIG. 5, the S/D region 608 corresponds to or is coupled to the BL 540, and is coupled to multiple transistors, i.e., the three nanoribbons 620. Each gate stack 616a, 616b, and 616c is coupled to a separate WL 550, as illustrated in FIG. 6B, for example.

To the right of each gate stack 616, the right end of the nanoribbon 620, i.e., the end of the nanoribbon 620 opposite the end coupled to the S/D region 608, is coupled to a capacitor 520. The gate stack 616 is between these two ends of the nanoribbon 620. In this example, the capacitor is a semiconductor-insulator-metal (SIM) capacitor, where the channel material 204 of the nanoribbon 620 forms a first plate (e.g., corresponding to the lower plate of the capacitor 520 of FIG. 5), and a metal material 604 surrounding the end of the nanoribbon 620 forms a second plate (e.g., corresponding to the upper plate of the capacitor 520 of FIG. 5). A dielectric material 602 is between the channel material 204 and the metal material 604, forming an insulator layer of the SIM capacitor. In some embodiments, the ends of the nanoribbon 620 acting as the first plate of the capacitor may be doped to increase their conductivity. In other embodiments, an inner metal layer is between the channel material 204 and the dielectric material 602, realizing a MIM capacitor that surrounds the end of the nanoribbon 620.

In the example of FIG. 6, the dielectric material 602 surrounds the nanoribbon 620, and the metal material 604 surrounds the dielectric material 602. The capacitors may be formed by exposing the ends of the nanoribbons 620 and conformally depositing the capacitor materials (e.g., the dielectric material 602 and the metal material 604) around the exposed ends of the nanoribbons 620. In other embodiments, the capacitor layers may not surround the ends of the nanoribbons 620 from all sides, but instead, may be formed over one side (e.g., the top side or the bottom side) or a subset of sides (e.g., the top and bottom sides) of the nanoribbons 620.

The dielectric material 602 forming the insulator layer may be deposited using any suitable technique for conformally depositing materials, as described above. The dielectric material 602 may include any suitable material for acting as a capacitor insulator. Examples of such materials include, but are not limited to, dielectric materials known for their applicability in ICs, such as low-k dielectric materials. Examples of dielectric materials that may be used as the dielectric material 602 may include, but are not limited to, silicon dioxide (SiO2), carbon-doped oxide (CDO), silicon nitride, fluorosilicate glass (FSG), silicon nitride, and organosilicates such as silsesquioxane, siloxane, or organosilicate glass. In some embodiments, the dielectric material 602 includes organic polymers such as polyimide, polynorbornenes, benzocyclobutene, perfluorocyclobutane, or polytetrafluoroethylene (PTFE). Still other examples of low-k dielectric materials that may be used as the dielectric material 602 include silicon-based polymeric dielectrics such as hydrogen silsesquioxane (HSQ) and methylsilsesquioxane (MSQ).

The metal material 604 forming the metal layer or metal plate of the capacitor 520 may also be deposited using any suitable technique for conformally depositing materials, as described above. The metal material 604 may include one or more of any suitable electrically conductive materials (conductors). Such materials may include any suitable electrically conductive material, alloy, or a stack of multiple electrically conductive materials. In some embodiments, the metal material 604 may include one or more metals or metal alloys, with metals such as copper, ruthenium, palladium, platinum, cobalt, nickel, hafnium, zirconium, titanium, tantalum, and aluminum. In some embodiments, the metal material 604 may include one or more electrically conductive alloys, oxides (e.g., conductive metal oxides), carbides (e.g., hafnium carbide, zirconium carbide, titanium carbide, tantalum carbide, and aluminum carbide, tungsten, tungsten carbide), or nitrides (e.g., hafnium nitride, zirconium nitride, titanium nitride, tantalum nitride, and aluminum nitride) of one or more metals.

FIG. 6B is a gate cross-section through the plane HH′ in FIG. 6A. As noted above, the three gate stacks 616a, 616b, and 616c along a vertical stack 600a of memory cells are not connected and are electrically isolated. In the x-z cross-section illustrated in FIG. 6B, memory cells in different stacks 600b, 600a, and 600c are physically and electrically connected in the horizontal direction by a gate line 618. For example, the gate stack 616a around the upper nanoribbon 620a is electrically and physically coupled to similar gate stacks around the upper nanoribbon in the stack 600b (to the right of the stack 600a) and the upper nanoribbon in the stack 600c (to the left of the stack 600a). These connected gate stacks form a gate line 618a. Similar gate lines 618b and 618c are along the lower nanoribbon channels in the stacks 600. The gate lines 618 extend in a direction perpendicular to the length of the nanoribbons 620. In this example, the nanoribbons 620 and, more generally, the individual memory cells extend from their first end (i.e., the end of the S/D region 608) to their second end (i.e., the capacitor end) along the y-direction, while the gate lines 618 extend in the x-direction.

The spacing of the nanoribbons within each stack 600 and between adjacent stacks 600, along with the selected deposition process parameters, may enable the formation of horizontal gate lines. For example, the horizontal distance 640 between nanoribbons 620 may be less than the vertical distance 630 between nanoribbons 620. The gate electrode 110 and gate dielectric 112 are deposited using a conformal deposition process, such as ALD, as discussed above. The deposition parameters (e.g., bias or voltage) may be selected such that the gate electrode 110 tends to deposit around the lower layers more quickly than around the upper layers, to prevent joined upper gate electrodes (e.g., electrodes along the gate line 618c) from blocking deposition of the gate electrode 110 around the lower gate electrodes (e.g., electrodes along the gate lines 618a and 618b). Unlike the gate stacks 616 forming the gate lines 618, the capacitors may not be connected together in the horizontal direction, e.g., the metal material 604 does not extend between the vertical stacks 300b, 300a, and 300c. The total thickness of the gate stacks 616 (e.g., the thickness of the gate dielectric 112 and gate electrode 110) may be greater than the total thickness of the insulator and metal capacitor layers (e.g., the thickness of the dielectric material 602 and metal material 604). In some embodiments, the channel material 204 may be thinned at the end used for forming the capacitors, so that the dielectric material 602 and metal material 604 may be deposited around each nanoribbon 620 without touching in the horizontal or vertical directions.

While not specifically, shown, regions of the memory cells outside of the nanoribbons 620, gate stacks 616, S/D regions 608, and metal material 604 of the capacitors may be filled in with a dielectric material, e.g., the dielectric material 106 described with respect to FIG. 1.

Each capacitor within each stack may be independently controlled, and, unlike the gate lines, capacitors across different stacks are not coupled in the horizontal direction. The metal material 604 forming the outer metal layer of each capacitor may be coupled to a plate line, corresponding to the PL 560 of FIG. 5. The independent electrical connections to each capacitor may be formed by extending the metal material 604 in the y-direction in the coordinate system shown to different lengths at different heights along the stack 600, so that the ends of the metal material 604 resemble a staircase, as shown in FIG. 6A. Vias at different positions in the y-direction can then connect to the different capacitors or different “steps” of the staircase.

More specifically, in FIG. 6A, each capacitor includes an extension region 610 coupled to a respective capacitor via 662, and the S/D region 608 is also coupled to a S/D via 660. The capacitor via 662 corresponds to the PL 560 in FIG. 2, while the S/D via 660 corresponds to the BL 540. Each of the memory cells in the stack 600 may be considered to be in a separate layer (e.g., a separate memory layer) of the device, and the extension region 610 extends along the memory layer, e.g., the extension region 610a is in the same layer as the nanoribbon 620a, and the extension region 610a is in a layer over the extension region 610b, which is in in the same layer as the nanoribbon 620b. Each extension region 610 is coupled to a respective capacitor via 662, and each of the capacitor vias 662 extends down from a front side of the device. The capacitor via 662a is coupled to the top memory layer, and in particular, to the extension region 610a. Each subsequent capacitor via 662b and 662c is coupled to the next extension region 610b or 610c in a lower memory layer. For example, the capacitor via 662c extends through the upper two memory layers. The capacitor vias 662 may have different lengths, i.e., heights in the z-direction. For example, the capacitor via 662a has a shorter height, also referred to as shorter length, than the capacitor via 662b.

The vias 660 and 662 may be formed from any conductive material 606, such as copper or another metal. In some embodiments, the vias 660 and/or 662 include multiple layers, e.g., one or more liner layers and a fill layer.

As described above, FIG. 6B illustrates three gate lines 618a, 618b, and 618c. In this illustration, each gate line 618 has an extension region that is similar to the extension regions 610 of FIG. 6A, except that the gate line extension regions extend in a perpendicular direction to the extension regions 610, e.g., the capacitor extension regions 610 extend in the y-direction while the gate extension regions extend in the x-direction. Each gate line 618 (and, in particular, each extension region of the gate line) is coupled to a respective gate via 664a, 664b, or 664c, where the gate vias 664 are similar to the capacitor vias 662, described above. The gate lines 618 and/or gate vias 664 correspond to the WL 550 of FIG. 5. The gate vias 664 may have different lengths, i.e., heights in the z-direction. For example, the gate via 664a has a shorter height, also referred to as shorter length, than the gate via 664b.

### Example Process for Fabricating Amorphous or Polycrystalline Nanoribbon Channels

FIG. 7 is a flow diagram of a process for fabricating a stack of amorphous or polycrystalline semiconductor channels, according to some embodiments of the present disclosure. The stack of amorphous or polycrystalline semiconductor channels may be used for transistors, e.g., the transistors of FIG. 2, or for memory devices, e.g., to form the access transistors for the 1T-1C memory cells illustrated in FIG. 6. In other embodiments, a similar process may be used to fabricate a semiconductor region of another shape, e.g., an amorphous or polycrystalline fin, as shown in FIG. 4.

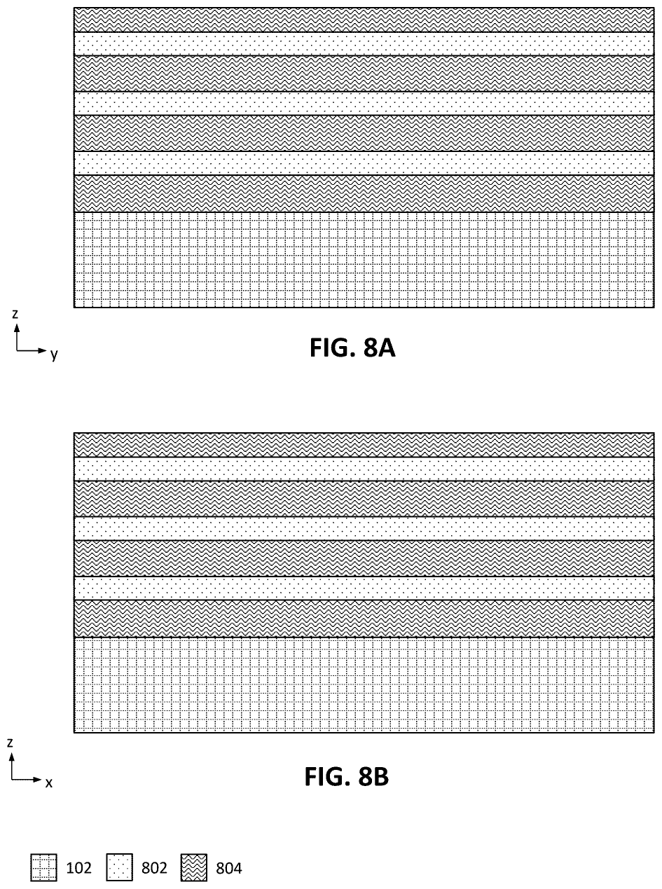

FIGS. 8-14 illustrate various steps in the processing method 700 of FIG. 7, according to some embodiments of the present disclosure. In general, the processing method 700 is performed across a wafer, with many individual stacks of transistors (or stacks of memory devices including the stacks of transistors) formed on the wafer. FIGS. 8-14 illustrate cross-sections of processing steps across several stacks of transistors. The processing method 700 describes a process of fabricating independent gates and gate lines across a stack of nanoribbons. Additional steps may be performed before, during, and/or after the process 700 to produce a device that includes the stacked transistors with independent top and bottom gates, e.g., to produce the vertically stacked memory cells shown in FIG. 5.

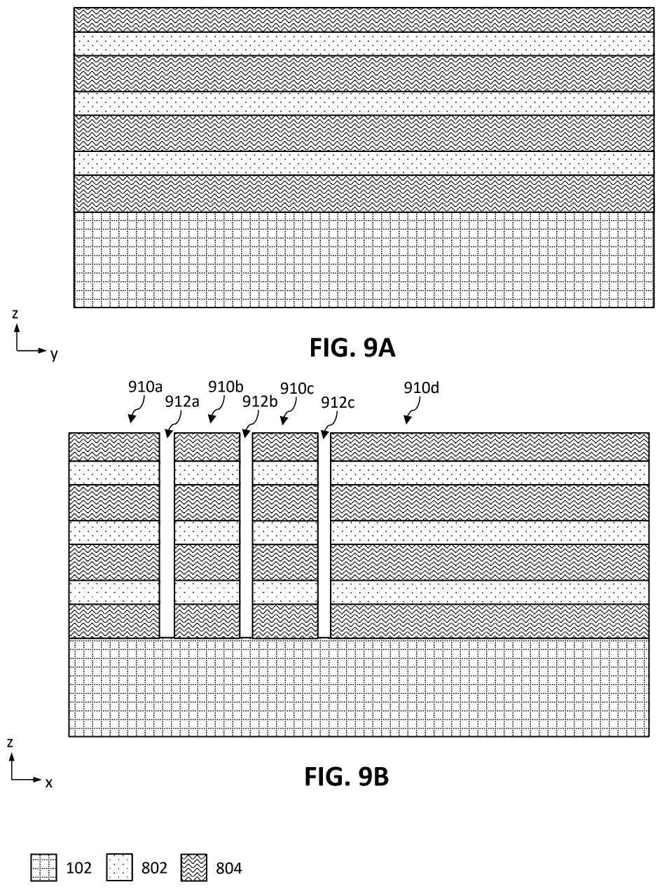

At 702, a process for growing alternating layers of two materials is performed. The two materials may both be sacrificial materials that are removed further in the process, as described below. FIGS. 8A and 8B are two perpendicular cross-sections illustrating layers of two sacrificial materials, according to some embodiments of the present disclosure. FIG. 8A is a cross-section in the y-z plane, and FIG. 8B is a cross-section in the x-z plane. FIGS. 9-14 illustrate the same two cross-sections at different stages of the processing method.

FIGS. 8A and 8B illustrate three layers of a first sacrificial material 802 interspersed with layers of a second sacrificial material 804. In this example, three layers of the first sacrificial material 802 are illustrated; in other examples, fewer or additional layers may be included. A layer of the second sacrificial material 804 is over the support structure 102, followed by a layer of the first sacrificial material 802, followed by another layer of the second sacrificial material 804, followed by another layer of the first sacrificial material 802, and so forth. In this example, the layers of the second sacrificial material 804 are relatively thick compared to the first sacrificial material 802. In other embodiments, the layers of the first sacrificial material 802 may be thicker, or the thicknesses may be equal or nearly equal.

The two sacrificial materials 802 and 804 include different materials. In one example, one of the sacrificial materials 802 and 804 is silicon, and the other is germanium. In another example, one or both of the first and second sacrificial materials 802 and 804 include silicon and germanium, but have different relative concentrations of silicon and germanium. For example, the first sacrificial material 802 is silicon, and the second sacrificial material 804 is a mixture of silicon and germanium. The sacrificial materials 802 and 804 may be chosen to have a similar crystal structure to each other, so that monocrystalline layers of the sacrificial materials 802 and 804 (or substantially monocrystalline layers, e.g., with a grain size of at least 5 nanometers, at least 20 nanometers, at least 50 nanometers, or at least 100 nanometers), may be formed over each other. In different embodiments, the sacrificial materials 802 and 804 may be formed of any suitable single-crystal material, such as sapphire, quartz, silicon, a compound of silicon (e.g., silicon oxide), indium phosphide, germanium or a germanium alloy (e.g., silicon germanium), gallium, arsenic (e.g., an arsenide 11 compound, where arsenic III is in combination with another element such as boron, aluminum, gallium, or indium), or any group III-V material (i.e., materials from groups III and V of the periodic system of elements).

Returning to FIG. 7, at 704, a process to etch channel material to form individuated stacks of semiconductor material is performed. FIG. 9 illustrates the layers of the sacrificial materials 802 and 804 after stacks have been etched to form individuated stacks, which serve as templates for different transistors or memory devices. As shown in FIG. 9B, portions of the alternating layers are removed, leaving the stacks and 910a, 910b, 910c, and 910d. The etching may be performed using a lithographic process, e.g., a mask may have been formed over the stacks 910a-910d so that the material under the masked regions is not removed. The stacks 910 are separated by etched regions 912a, 912b, and 912c, e.g., the etched region 912a is between the stacks 910a and 910b. In this example, which may be used to form the stacks 600 of memory cells, the stacks 910 are fairly close together, i.e., the etched regions 912 relatively narrow in the x-direction, so that the gate electrode 110 can join adjacent memory cells in the x-direction, as shown in FIG. 6B. Furthermore, in this example, the stack 910d is wider in the x-direction than the other stacks; while the stacks 910a-910c may be used to form transistors or memory devices, the stack 910b may be used to form gate extension regions, e.g., the gate extension regions shown in FIG. 6B. In other examples, the stacks 910 and/or etched regions 912 may have different widths or different relative widths than shown in FIG. 9B. FIG. 9A illustrates a cross-section through one of the stacks, e.g., the stack 910b.

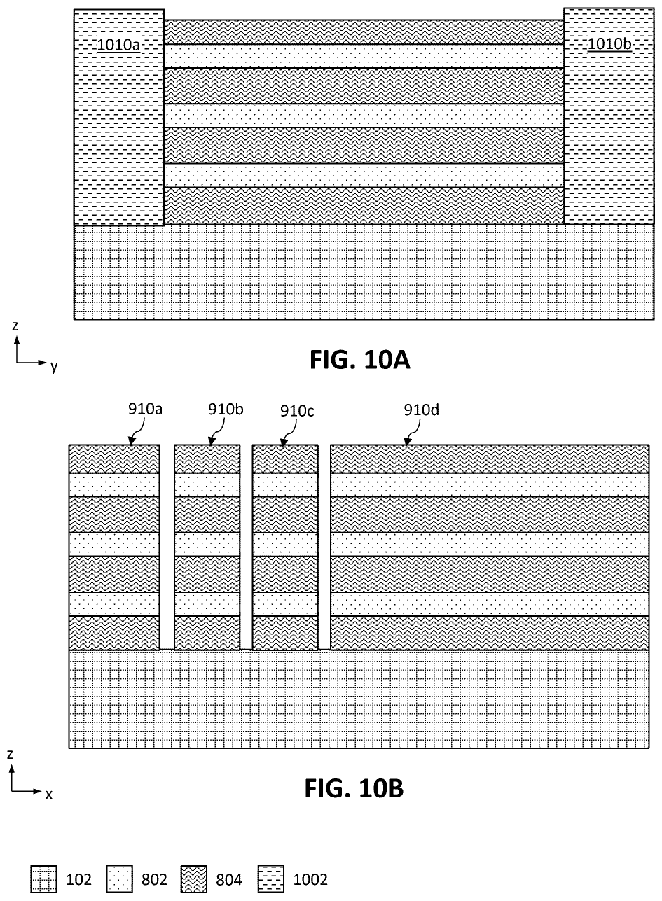

Returning to FIG. 7, at 706, a process to form anchors at opposite ends of the semiconductor stacks is performed. FIGS. 10A and 10B illustrate formation of anchors 1010a and 1010b around the stacks of the layered sacrificial materials. For example, at each end of the stacks 910 in the y-direction, a portion of the stack may be replaced with an anchor that provides physical support to the second sacrificial material 804 during later processing, e.g., when the first sacrificial material 802 is removed. In some embodiments, the anchor material 1002 is an S/D material, e.g., the material of the S/D regions 108, described above. In other embodiments, a temporary anchor material is used, and replaced at a later processing stage with the S/D region 108.

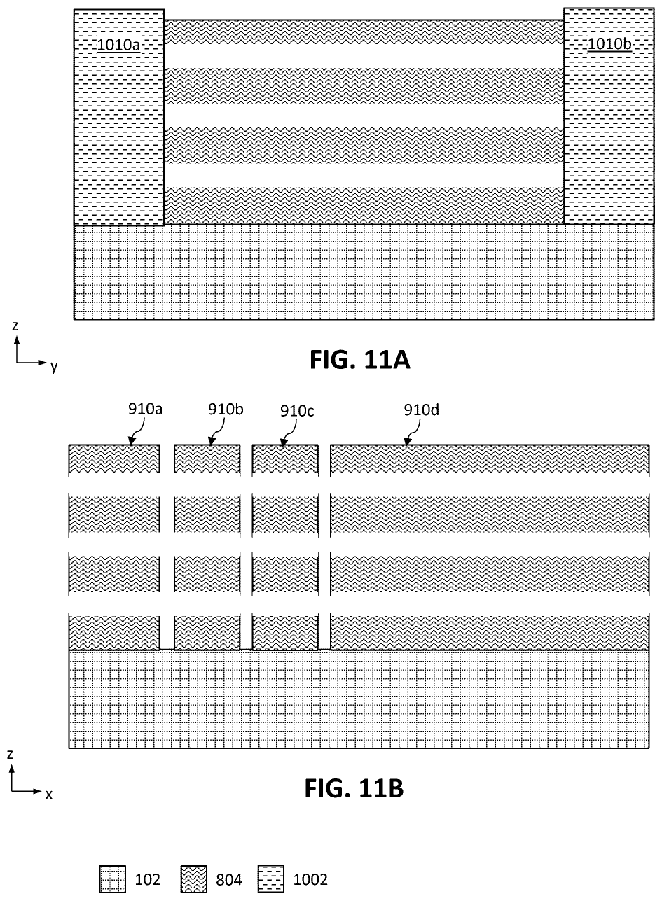

At 708, the first sacrificial material is removed from the stacks. FIGS. 11A and 11B illustrate removal of the first sacrificial material 802 from the stacks 910. In FIG. 11, the first sacrificial material 802 has been etched, leaving the upper semiconductor structures of the second sacrificial material 804 floating between the anchors 1010, as illustrated in FIG. 11A. The first sacrificial material 802 may be removed using an etching process, such as dry etch, wet etch, or a combination. An etchant material used to remove the first sacrificial material 802 is selective to the first sacrificial material 802, i.e., the etchant removes the first sacrificial material 802 but does not remove the second sacrificial material 804.

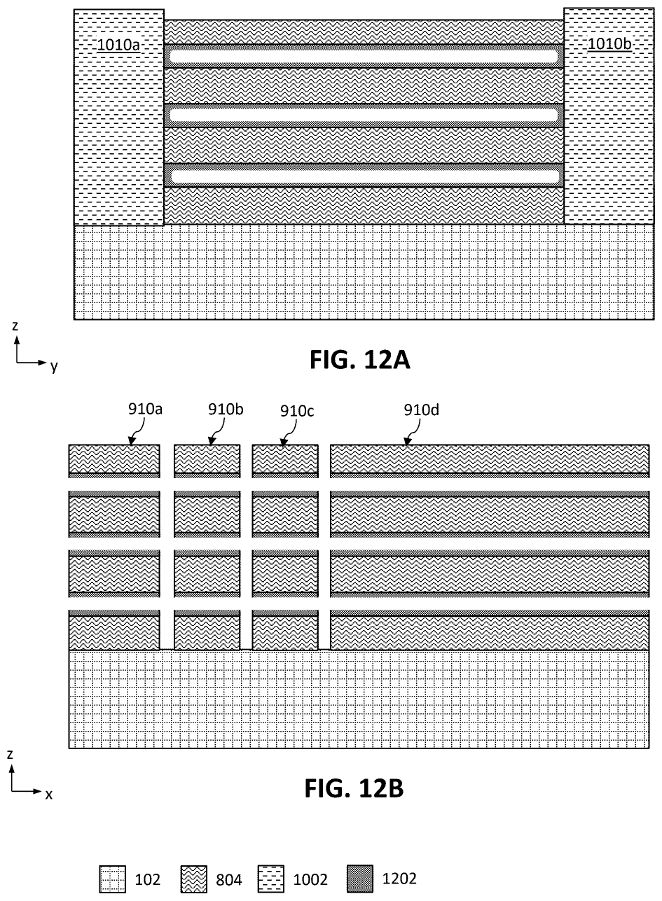

At 710, a channel material is grown in the area etched areas where the first sacrificial material had been. The sacrificial materials were used to form a template into which the channel material can be deposited. FIGS. 12A and 12B illustrate a first stage of channel material deposition. The channel material 1202 may include any of the channel materials 204 described above, e.g., any amorphous or polycrystalline semiconductor material. The channel material 1202 is deposited using a conformal deposition process, as described above. As illustrated, the channel material 1202 is deposited onto to the exposed surfaces, e.g., over the tops and bottoms of the second sacrificial material 804, and along the edges of the anchors 1010. The channel material 1202 begins to fill in the areas from which the first sacrificial material 804 were removed.

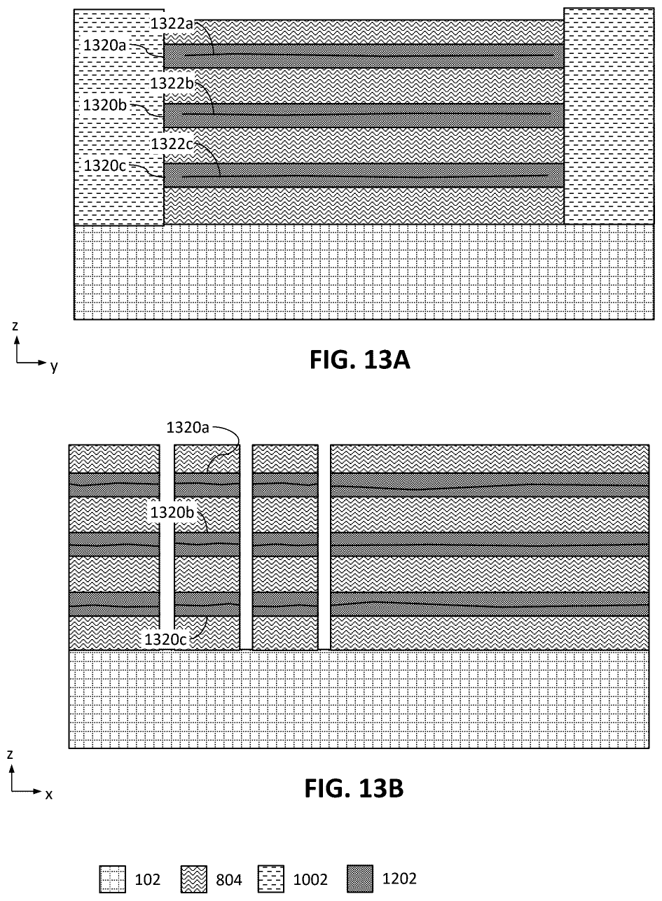

FIGS. 13A and 13B illustrate further deposition of channel material. In FIGS. 13A and 13B, the areas from which the first sacrificial material 804 were removed are now filled in with the channel material 1202, forming a stack of semiconductor structures 1320a, 1320b, and 1320c. Each semiconductor structure 1320 has a seam 1322a, 1322b, or 1322c, which are similar to the seams 222 described with respect to FIGS. 2 and 3. FIGS. 13A and 13B show perpendicular cross-sections through the semiconductor structures 1320, and FIG. 13B shows cross-sections through three additional stacks corresponding to the stacks 910a, 910c, and 910d of FIG. 9.

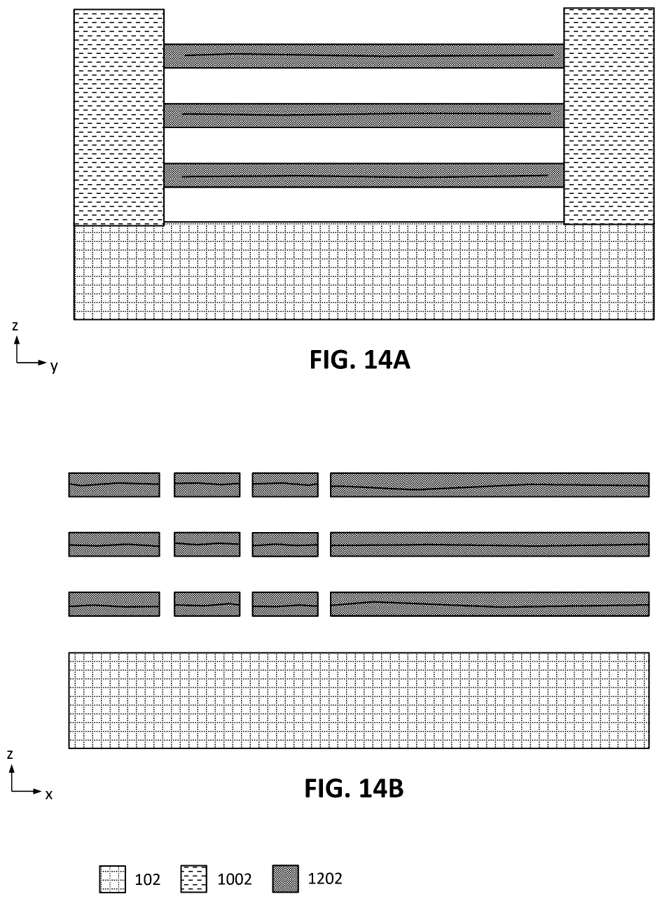

At 712, the second sacrificial material is removed from the stacks. FIGS. 14A and 14B illustrate removal of the second sacrificial material 804. As shown in FIG. 14A, the semiconductor structures 1320 are floating between the anchors 1010. The second sacrificial material 804 may be removed using an etching process, such as dry etch, wet etch, or a combination. An etchant material used to remove the second sacrificial material 804 is selective to the second sacrificial material 804, e.g., the etchant removes the second sacrificial material 804 but does not remove the channel material 1202. A process for forming transistors around the semiconductor structures 1320 may be performed, e.g., depositing a gate stack around the semiconductor structures 1320, and, if needed, replacing the anchors 1010 with source/drain material, to achieve the transistor shown in FIG. 2. Alternatively, a process for forming memory cells around the semiconductor structures 1320 may be performed, e.g., depositing a gate stack around each semiconductor structures 1320, and depositing a capacitor around the end of each of the semiconductor structures 1320, to achieve the memory cells shown in FIG. 6.

### Example Devices

The circuit devices with three-dimensional semiconductor devices with amorphous or polycrystalline channel materials disclosed herein may be included in any suitable electronic device. FIGS. 15-19 illustrate various examples of apparatuses that may include the one or more transistors or memory cells disclosed herein, which may have been fabricated using the processes disclosed herein.

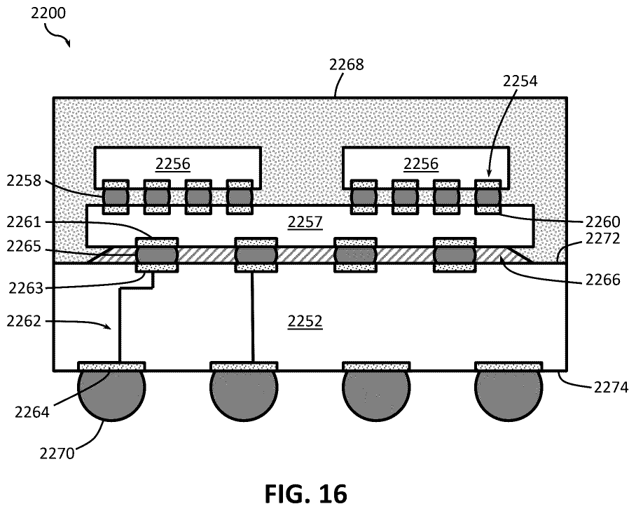

FIG. 15 illustrates top views of a wafer 2000 and dies 2002 that may include one or more three-dimensional semiconductor devices with amorphous or polycrystalline channel materials in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 16. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more three-dimensional semiconductor devices with amorphous or polycrystalline channel materials as described herein). After the fabrication of the semiconductor product is complete (e.g., after manufacture of any embodiment of the memory devices as described herein), the wafer 2000 may undergo a singulation process in which each of the dies 2002 is separated from one another to provide discrete “chips” of the semiconductor product. In particular, devices that include one or more three-dimensional semiconductor devices with amorphous or polycrystalline channel materials as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device (e.g., a hysteretic memory device), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 16) or other logic that is configured to store information in the memory devices or execute instructions stored in the memory array.

FIG. 16 is a side, cross-sectional view of an example IC package 2200 that may include one or more three-dimensional semiconductor devices with amorphous or polycrystalline channel materials in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 16 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 16 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

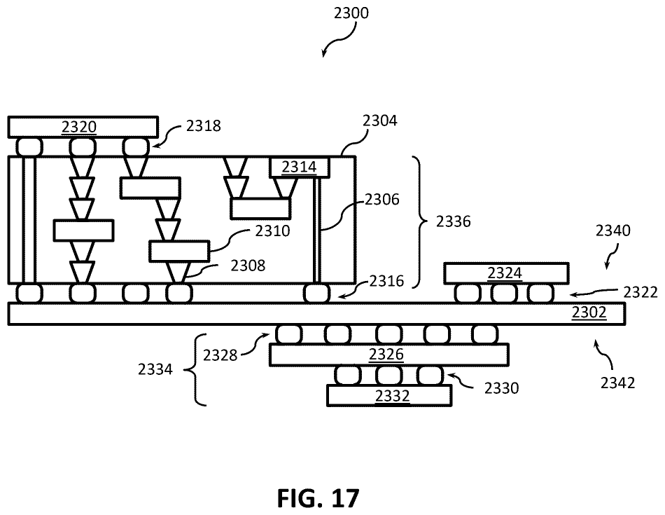

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 16 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 17.

The dies 2256 may take the form of any of the embodiments of the die 2002 discussed herein (e.g., may include any of the embodiments of the IC devices with one or more three-dimensional semiconductor devices with amorphous or polycrystalline channel materials as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include one or more IC devices with one or more three-dimensional semiconductor devices with amorphous or polycrystalline channel materials, e.g., as discussed above; in some embodiments, at least some of the dies 2256 may not include any three-dimensional semiconductor devices with amorphous or polycrystalline channel materials.

The IC package 2200 illustrated in FIG. 16 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 16, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 17 is a cross-sectional side view of an IC device assembly 2300 that may include components having one or more three-dimensional semiconductor devices with amorphous or polycrystalline channel materials in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include one or more three-dimensional semiconductor devices with amorphous or polycrystalline channel materials in accordance with any of the embodiments disclosed herein; e.g., any of the IC packages discussed below with reference to the IC device assembly 2300 may take the form of any of the embodiments of the IC package 2200 discussed above with reference to FIG. 16 (e.g., may include one or more three-dimensional semiconductor devices with amorphous or polycrystalline channel materials provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 17 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 17), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 15), an IC device, or any other suitable component. In particular, the IC package 2320 may include one or more three-dimensional semiconductor devices with amorphous or polycrystalline channel materials as described herein. Although a single IC package 2320 is shown in FIG. 17, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 17, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 17 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

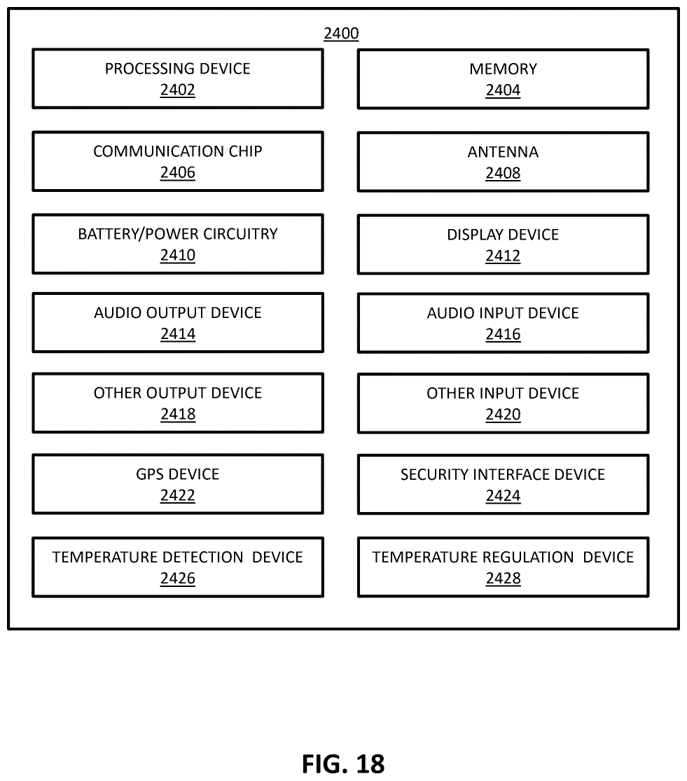

FIG. 18 is a block diagram of an example computing device 2400 that may include one or more components including one or more IC devices with one or more three-dimensional semiconductor devices with amorphous or polycrystalline channel materials in accordance with any of the embodiments disclosed herein. For example, any suitable ones of the components of the computing device 2400 may include a die (e.g., the die 2002 of FIG. 15) having one or more three-dimensional semiconductor devices with amorphous or polycrystalline channel materials as described herein. Any one or more of the components of the computing device 2400 may include, or be included in, an IC package 2200 of FIG. 16 or an IC device 2300 of FIG. 17.

A number of components are illustrated in FIG. 18 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 18, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

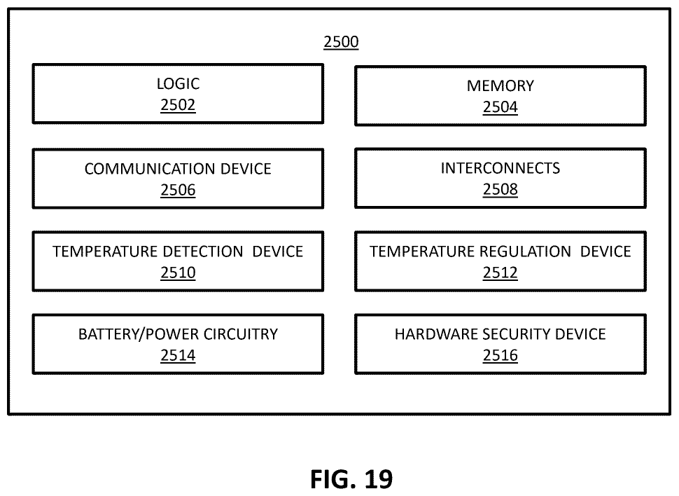

FIG. 19 is a block diagram of an example processing device 2500 that may include one or more IC devices with one or more three-dimensional semiconductor devices with amorphous or polycrystalline channel materials in accordance with any of the embodiments disclosed herein. For example, any suitable ones of the components of the processing device 2500 may include a die (e.g., the die 2002 of FIG. 15) having one or more three-dimensional semiconductor devices with amorphous or polycrystalline channel materials as described herein. Any one or more of the components of the processing device 2500 may include, or be included in, an IC device 1400 (FIG. 17). Any one or more of the components of the processing device 2500 may include, or be included in, an IC package 2200 of FIG. 16 or an IC device 2300 of FIG. 17. Any one or more of the components of the processing device 2500 may include, or be included in, a computing device 2400 of FIG. 18; for example, the processing device 2500 may be the processing device 2402 of the computing device 2400.

A number of components are illustrated in FIG. 19 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 19, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 1604 (FIG. 18). In some embodiments, the memory 2504 may be a designated device configured to provide storage functionality for the components of the processing device 2500 (i.e., local), while the memory 1604 may be configured to provide system-level storage functionality for the entire computing device 1600 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 1606 (FIG. 18). In some embodiments, the communication device 2506 may be a designated device configured to provide communication functionality for the components of the processing device 2500 (i.e., local), while the communication chip 1606 may be configured to provide system-level communication functionality for the entire computing device 1600 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 of FIG. 18 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 of FIG. 18 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 of FIG. 18. In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 of FIG. 18. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The above description of illustrated implementations of the disclosure, including what is described in the Abstract, is not intended to be exhaustive or to limit the disclosure to the precise forms disclosed. Unless specified otherwise, in various embodiments, features described with respect to one of the drawings may be combined with those described with respect to other drawings.

### Select Examples

The following paragraphs provide various examples of the embodiments disclosed herein.

Example 1 provides a transistor including a semiconductor region extending in a first direction and a second direction, the first direction perpendicular to the second direction, and the semiconductor region having a first length in the first direction; a conductive region wrapping around at least three sides of the semiconductor region, the conductive region having a second length in the first direction that is less than the first length; and a seam extending along the semiconductor region, the seam visible in a cross-section through the semiconductor region and the conductive region, the cross-section perpendicular to the first direction.

Example 2 provides the transistor of example 1, where the semiconductor region has a fin shape, and the first length is the fin length.

Example 3 provides the transistor of example 1 or 2, where the conductive region wraps around a top and two sides of the semiconductor region.

Example 4 provides the transistor of example 1, where in the cross-section, the conductive region wraps around the semiconductor region.

Example 5 provides the transistor of example 4, where the semiconductor region is a first semiconductor region, the transistor further including a second semiconductor region stacked over the first semiconductor region.

Example 6 provides the transistor of any of examples 1-5, where the semiconductor region includes a polycrystalline material.

Example 7 provides the transistor of example 6, where the semiconductor region has a width in the second direction, the polycrystalline material has a grain size of less than half the width.

Example 8 provides the transistor of example 6, where the semiconductor region has a height in a third direction that is perpendicular to the first direction and the second direction, and the polycrystalline material has a grain size of less than half the height.

Example 9 provides the transistor of any of examples 1-5, where the semiconductor region includes an amorphous material.

Example 10 provides a device including a first channel region extending in a first direction; a second channel region extending in the first direction; and a gate around the first channel region and the second channel region; where, in a cross-section through the first channel region, the second channel region, and the gate in a plane perpendicular to the first direction, the first channel region and the second channel region each have a seam extending across their widths.

Example 11 provides the device of example 10, where the widths of the first and second channel regions are along a second direction perpendicular to the first direction, and the first and second channel regions are adjacent to each other in the second direction.

Example 12 provides the device of example 11, where each of the first channel region and second channel region is coupled to a respective capacitor.

Example 13 provides the device of example 10, where the widths of the first and second channel regions are along a second direction perpendicular to the first direction, and the first channel region and second channel region are at different positions along a third direction perpendicular to the first direction and the second direction.

Example 14 provides the device of any of examples 10-13, where the first channel region and the channel region are further coupled to a first source or drain region.

Example 15 provides the device of any of examples 10-14, where, in the cross-section, the first channel region includes a plurality of crystal grains extending from an edge of the first channel region towards the seam in the first channel region.

Example 16 provides the device of any of examples 10-15, where, in the cross-section, the seam in the first channel region is approximately mid-way between a base and a top of the first channel region.

Example 17 provides the device of any of examples 10-16, where, in the cross-section, the seam in the first channel region is at substantially a same height as the seam in the second channel region.

Example 18 provides a memory including an access transistor including a semiconductor channel material, where the semiconductor channel material is amorphous or polycrystalline; and a capacitor coupled to the access transistor, the capacitor including a dielectric region and a conductive region, where the dielectric region and the conductive region are over an end of the semiconductor channel material.

Example 19 provides the memory of example 18, where the semiconductor channel material is amorphous.

Example 20 provides the memory of example 18 or 19, the access transistor including a gate, where the semiconductor channel material has a seam in a cross-section through the gate.

Example 21 provides an IC package that includes an IC die, including one or more of the IC devices according to any one of the preceding examples. The IC package may also include a further component, coupled to the IC die.

Example 22 provides the IC package according to example 21, where the further component is one of a package substrate, a flexible substrate, or an interposer.

Example 23 provides the IC package according to examples 21 or 22, where the further component is coupled to the IC die via one or more first level interconnects.

Example 24 provides the IC package according to example 23, where the one or more first level interconnects include one or more solder bumps, solder posts, or bond wires.

Example 25 provides a computing device that includes a circuit board; and an IC die coupled to the circuit board, where the IC die includes one or more of the transistor/IC devices according to any one of the preceding examples (e.g., transistor/IC devices according to any one of examples 1-20), and/or the IC die is included in the IC package according to any one of the preceding examples (e.g., the IC package according to any one of examples 21-24).

Example 26 provides the computing device according to example 25, where the computing device is a wearable computing device (e.g., a smart watch) or hand-held computing device (e.g., a mobile phone).

Example 27 provides the computing device according to examples 25 or 26, where the computing device is a server processor.

Example 28 provides the computing device according to examples 25 or 26, where the computing device is a motherboard.

Example 29 provides the computing device according to any one of examples 25-28, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. A transistor comprising:
a semiconductor region extending in a first direction and a second direction, the first direction perpendicular to the second direction, and the semiconductor region having a first length in the first direction;
a conductive region wrapping around at least three sides of the semiconductor region, the conductive region having a second length in the first direction that is less than the first length; and
a seam extending along the semiconductor region, the seam visible in a cross-section through the semiconductor region and the conductive region, the cross-section perpendicular to the first direction.

2. The transistor of claim 1, wherein the semiconductor region has a fin shape, and the first length is a length of the fin.

3. The transistor of claim 1, wherein the conductive region wraps around a top and two sides of the semiconductor region.

4. The transistor of claim 1, wherein in the cross-section, the conductive region wraps around the semiconductor region.

5. The transistor of claim 4, wherein the semiconductor region is a first semiconductor region, the transistor further comprising a second semiconductor region stacked over the first semiconductor region.

6. The transistor of claim 1, wherein the semiconductor region comprises a polycrystalline material.

7. The transistor of claim 6, wherein the semiconductor region has a width in the second direction, the polycrystalline material has a grain size of less than half the width.

8. The transistor of claim 6, wherein the semiconductor region has a height in a third direction that is perpendicular to the first direction and the second direction, and the polycrystalline material has a grain size of less than half the height.

9. The transistor of claim 1, wherein the semiconductor region comprises an amorphous material.

10. A device comprising:
a first channel region extending in a first direction;
a second channel region extending in the first direction; and
a gate around the first channel region and the second channel region;
wherein, in a cross-section through the first channel region, the second channel region, and the gate in a plane perpendicular to the first direction, the first channel region and the second channel region each have a seam extending across their widths.

11. The device of claim 10, wherein the widths of the first and second channel regions are along a second direction perpendicular to the first direction, and the first and second channel regions are adjacent to each other in the second direction.

12. The device of claim 11, wherein each of the first channel region and second channel region is coupled to a respective capacitor.

13. The device of claim 10, wherein the widths of the first and second channel regions are along a second direction perpendicular to the first direction, and the first channel region and second channel region are at different positions along a third direction perpendicular to the first direction and the second direction.

14. The device of claim 10, wherein the first channel region and the second channel region are further coupled to a first source or drain region.

15. The device of claim 10, wherein, in the cross-section, the first channel region comprises a plurality of crystal grains extending from an edge of the first channel region towards the seam in the first channel region.

16. The device of claim 10, wherein, in the cross-section, the seam in the first channel region is approximately mid-way between a base and a top of the first channel region.

17. The device of claim 10, wherein, in the cross-section, the seam in the first channel region is at substantially a same height as the seam in the second channel region.

18. A memory comprising:
an access transistor comprising a semiconductor channel material, wherein the semiconductor channel material is amorphous or polycrystalline; and
a capacitor coupled to the access transistor, the capacitor comprising a dielectric region and a conductive region, wherein the dielectric region and the conductive region are over an end of the semiconductor channel material.

19. The memory of claim 18, wherein the semiconductor channel material is amorphous.

20. The memory of claim 18, the access transistor comprising a gate, wherein the semiconductor channel material has a seam in a cross-section through the gate.
